(19) United States
(12) Patent Application Publication
(10) Pub. No.: US 2008/0283278 A1
(43) Pub. Date: Nov. 20, 2008

(54) Flexible Circuit Substrate

(76) Inventors: Li Ping Wang, Ningbo (CN); Xiao Dong Wang, Singapore (SG); Jian Xia Gao, Singapore (SG)

Correspondence Address: 3M INNOVATIVE PROPERTIES COMPANY, PO BOX 33427, ST. PAUL, MN, 55133-3427, US

(21) Appl. No.: 11/908,741

(22) PCT Filed: Apr. 4, 2006
(86) PCT No.: PCT/US06/12218

§ 371 Date: Apr. 16, 2008

(30) Foreign Application Priority Data
Apr. 8, 2005 (SG) 200502164-7

(51) Int. Cl. H05K 1/00

(52) U.S. Cl. 174/254

(57) ABSTRACT

The present invention is directed to a substrate for subsequent eutectic bonding with a subsequently applied metal to provide, or as a precursor to the provision of, a circuit substrate. The circuit substrate comprises a dielectric film and a layer of an oxide or oxides of a metal on the film. The metal oxide layer has been formed by sputtering the metal of the metal oxide or oxides onto a surface of the film in the presence of an inert atmosphere save for at least one reactive gas content to provide the oxygen of the oxides.

### FIELD

This invention relates to a flexible circuit substrate, more particularly, but not limited thereto, an adhesiveless flexible circuit substrate including a tie layer structure and to a process for the manufacture thereof.

### BACKGROUND

With the electronics industry moving toward thinner, lighter, flexible and more functionally integrated products, there is an increasing demand for fine pitch flexible circuits for certain advanced applications such as chip-on-flex (COF).

Adhesiveless flexible circuit substrates are widely employed for high performance flexible circuit manufacturing. They are normally produced by any one of the following three approaches:
(1) cast liquid polyimide on copper foil,
(2) high temperature lamination of copper foil with a polyimide substrate; and
(3) vacuum deposition of metal on a polyimide film followed by an electroplating technique.

Vacuum deposition combined with an electroplating technique has been the most promising of these approaches for finer pitch applications. Its manufacturing process is fully compatible with both additive flexible circuit making processes (i.e. wherein the circuit traces are formed by electroplating into resist-defined patterns) and subtractive flexible circuit making processes (i.e. wherein the circuit traces are formed by etching away the exposed regions defined by resist patterns).

The flexible circuit substrate made by vacuum deposition and subsequent electroplating technique is described in U.S. Pat. Nos. 6,171,714; 5,112,462; and 5,480,730. The production process typically starts with a plasma treatment of a polymer film. A tie layer of metal is deposited by vacuum sputtering or vacuum evaporation in an inert atmosphere. The tie layer can be a single layer, dual layers or multiple layers comprising chromium (Cr), nickel (Ni), cobalt (Co), molybdenum (Mo) etc., or their related alloys. Tie layer thickness can be as thick as several hundreds of Angstroms and as thin as a few Angstroms. A copper seed layer of about several tens of nanometers to 2 micrometers is then applied to the tie layer using a vacuum deposition process to provide sufficient electrical conductivity to permit electroplating of copper to a desired thickness.

Flexible circuits are normally manufactured using additive, semi-additive or subtractive process. For both additive and subtractive processes it is necessary to remove any tie layer between copper patterns to isolate copper traces. Finish plating such as Sn or Ni/Au may be coated on the circuit traces as required by a particular application, for example COF assembly.

Eutectic bonding has been one of the popular COF assembly technologies, particularly for the assembly of the increasingly finer pitch semiconductor chips and tin plated flexible circuits. In this technology, a bonding of flexible circuit with IC chip is achieved by forming a Sn/Au eutectic alloy after tin and Au bumps are contacted and heated at or above the temperature of the Sn/Au eutectic point. An appropriate choice of bonding parameters (bonder stage temperature, tool temperatures, bonding force etc.) is important to ensure a good bonding quality.

Normal defects occurring in eutectic bonding of flexible circuits include trace lifting and PI/Cu interface delamination 1 at edge of gold bump 2, as illustrated in FIG. 1 and FIG. 2. Relatively high bonding temperature and bonding force are good for elimination of trace lifting problem, however they exacerbate PI/Cu interface delamination 1 further. In practice, some flexible circuits made from sputtering flexible substrate have small bonding process window.

There is a need to provide flexible circuits with a relatively wide eutectic bonding process window and a reduced severity of PI/Cu interface delamination.

It is therefore an objective of at least one embodiment of the present invention to provide a flexible circuit substrate that prevents or at least reduces PI/Cu interface delamination during bonding process; or

To provide a flexible circuit substrate having improved retention of peel strength after thermal aging of flexible circuit substrate.

### SUMMARY OF THE INVENTION

In a first aspect the present invention provides a substrate for subsequent eutectic bonding with a subsequently applied metal to provide, or as a precursor to the provision of, a circuit substrate, said substrate comprising a dielectric film and a layer of an oxide or oxides of a metal on the film, wherein the metal oxide layer has been formed by sputtering the metal of the metal oxide or oxides onto a surface of the film in the presence of an inert atmosphere save for at least one reactive gas content to provide the oxygen of the oxides.

In a further aspect the present invention provides a substrate for subsequent eutectic bonding with a subsequently applied metal to provide, or as a precursor to the provision of, a circuit substrate, said substrate comprising
(1) a dielectric film;
(2) a tie layer comprising an oxide of a metal or oxides of metal alloy on the film upon said dielectric film; and
(3) a layer of a metal or metals forming a trace upon said tie layer,
   wherein the metal oxide layer has been formed by sputtering the metal of the metal oxide or oxides onto a surface of the film in the presence of an inert atmosphere save for at least one reactive gas content to provide the oxygen of the oxides.

In a further aspect the present invention provides a circuit, said circuit being of
(1) a dielectric film;
(2) a tie layer comprising an oxide or oxides of a metal or metals on said dielectric film; and
(3) a layer of a metal or metals forming a trace upon said tie layer,
(4) a layer of tin or tin alloy is on the metal traces
   wherein the oxide layer has been formed by sputtering the metal of the oxide or oxides onto a surface of the film in the presence of an inert atmosphere save for at least one reactive gas content to provide the oxygen of the oxides.

In a further aspect the present invention provides a substrate for subsequent eutectic bonding with a subsequently applied metal to provide, or as a precursor to the provision of, a circuit substrate, said substrate comprising a metal oxide tie layer sandwiched between a dielectric film layer and a metal layer wherein the metal oxide tie layer has been formed by sputtering a metal onto the dielectric film layer in a substantially inert atmosphere additionally containing a reactive gas.

In a further aspect the present invention provides a process for the production of a substrate for subsequent eutectic bonding with a subsequently applied metal to provide or as a precursor to the provision of a circuit substrate comprising the step of:
sputtering a metal in an inert atmosphere save for at least one reactive gas to provide the oxygen to the metal or metals and thereby deposit a ‘tie layer’ of oxide or oxides of the metal or metals onto a surface of a dielectric film.

In a further aspect the present invention provides a process for the production of a substrate for subsequent eutectic bonding with a subsequently applied metal to provide or as a precursor to the provision of a circuit substrate comprising the steps of:
sputtering a metal in an inert atmosphere save for at least one reactive gas to provide the oxygen to the metal or metals and thereby deposit a ‘tie layer’ of oxide or oxides of the metal onto a surface of a dielectric film; and
depositing a metal layer upon the tie layer.

In a further aspect the present invention provides a process for the production of a substrate for subsequent eutectic bonding with a subsequently applied metal to provide or as a precursor to the provision of a circuit substrate comprising the steps of:
sputtering a metal in an inert atmosphere save for at least one reactive gas to provide the oxygen to the metal and thereby deposit a ‘tie layer’ of oxide or oxides of the metal onto a surface of a dielectric film;
depositing a metal layer upon the tie layer; and
bonding an electronic interconnecting device to said metal layer.

Preferably the layer of metal or metals is patterned to form traces, said patterning may be performed by either additive, semi-additive or subtractive process to form traces.

Preferably the tie layer is patterned commensurate with the metal or metals traces to expose the dielectric film.

Preferably said metal or metals traces are bonded to electronic interconnecting device such as IC chip, PCB (printed circuit board), etc. by eutectic bonding.

Preferably said bonding between the electronic interconnecting device and the metal or metals layer is a eutectic bond. The eutectic bond may comprise a mixture of tin and gold.

The chip may be an IC Chip with gold bumps. Desirably tin is plated on said metal or metal traces. Preferably the eutectic bond is formed between the plated tin on traces and gold bump on IC chip.

The dielectric film may be any suitable polyimide including, but not limited to, those available under the tradename UPILEX from Ube Industries, Ltd., Tokyo, Japan; under the tradename APICAL from Kaneka High-Tech Materials, Inc., Pasadena, Tex. (USA); and available under the trade names KAPTON, including KAPTON E, KAPTON EN, KAPTON H, and KAPTON V from DuPont High Performance Materials, Circleville, Ohio (USA). Other polymers such as poly(ethylene terephthalate) (PET), poly(ethylene naphthalate) (PEN) available under trade name of MYLAR and TEONEX respectively from DuPont Tiejin Films, Hopewell, Va. (USA), polycarbonate and polyetherimide (PEI) available under trade name of LEXAN and ULTEM respectively from General Electric Plastics, Pittsfield, Mass. (USA), polyetheretherketone available under trade name PEEK from Victrex Polymer, Lancashire (UK), etc. can be used. Preferably the film is a polyimide. Desirably the dielectric film is flexible.

The inert atmosphere may be argon, neon, and nitrogen, among others. Preferably the inert atmosphere is argon.

The reactive gas is capable of supplying oxygen to form the metal oxide or metal oxides. Preferably the reactive gas is oxygen. Other suitable reactive gases include nitrous oxide, nitrogen dioxide, dinitrogen pentoxide, dinitrogen tetraoxide, among others.

The metal layer may be deposited onto the tie layer by electrodeposition, electroless deposition, sputtering, evaporation, among others.

The metal component of the metal oxide layer may be, but is not limited to, nickel, chromium, cobalt, molybdenum, copper and alloys thereof. Preferably the metal component of the metal oxide layer contains nickel.

Suitable materials for the metal layer include, but are not limited to copper, aluminum, silver, gold or their alloy.

The term ‘comprising’ as used in this specification and claim set means “consisting at least in part of”, that is to say when interpreting independent claims including that term the features prefaced by that term in each claim will need to be present but other features can also be present.

Unless indicated otherwise, the term ‘metal’ is intended to cover one or more metal or metal alloy.

To those skilled in the art to which the invention relates, many changes in construction and widely differing embodiments and applications of the invention will suggest themselves without departing from the scope of the invention as defined in the appended claims. The disclosures and the descriptions herein are purely illustrative and are not intended to be in any sense limiting.

### DEFINITIONS

Where in the specification the following terms are used they have the following meanings:

‘trace’—metallic connections on a printed circuit board (PCB) that allow electricity to flow between electronic components.

‘pitch’—the distance between the midlines of two adjacent traces.

‘trace lifting’—trace separation from die bump during peeling test after bonding.

### BRIEF DESCRIPTION OF THE DRAWINGS

The present invention will now be further described with reference to the figures in the accompanying drawings in which:

FIG. 1 is a plain view of PI/Cu interface delamination 1 viewed from the polyimide (PI) film side after eutectic bonding;

FIG. 2 is a sectional view of PI/Cu interface delamination 1 along the trace direction.

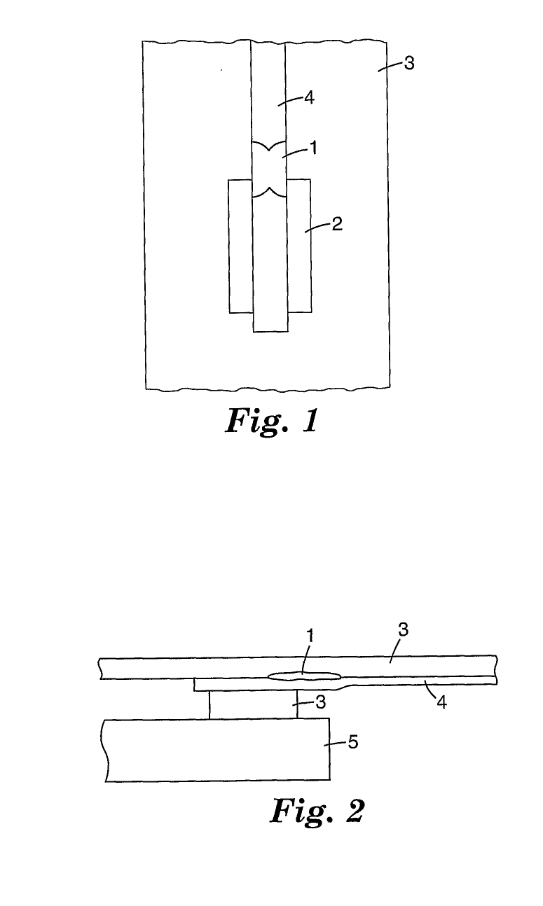

### DETAILED DESCRIPTION

We have found in the manufacturing of substrates and flexible circuits, that tie layer composition has a dominative impact on subsequent bonding and PI/Cu interface delamination performance.

According to one embodiment of the present invention, a NiCrOₓ tie layer can provide a flexible circuit with a substantially improved resistance to PI/Cu interface delamination over the normal nickel-chromium tie layer having a similar tie layer thickness during eutectic bonding. It was found that a NiCrOₓ tie layer had significantly reduced PI/Cu interface delamination during eutectic bonding as compared to a NiCr tie layer.

It was also found that the thickness of the oxide tie layer could impact the bonding and PI/Cu interface delamination performance. Although the suitable thickness of a tie layer will depend on various factors, it was found that a thickness equal to or greater than 13 Angstroms provided favorable results. Preferably, the tie layer thickness is from about 13 Angstroms to about 300 Angstroms. Tie layer thickness was evaluated by dissolving the tie layer into 15% aqua regia and testing by ICP (Inductively Coupled Plasma Atomic Emission Spectrum), wherein thickness conversion from element concentrations is based on the density of solid materials.

Here, NiCrOₓ represents any possible stoichiometry of nickel (Ni), chromium (Cr) and oxygen (O) elements in the tie layer. Various degrees of oxidation of NiCr alloy, or any form of a mixture of NiₓO_{y}, CrₓO_{y}, Ni and/or Cr are included. Without wishing to be bound to any particular theory, we believe that the effect of oxygen in the tie layer to resist PI/Cu interface delamination in eutectic bonding is applicable to any tie layer containing nickel alloy, including dual tie layers and gradual tie layers containing nickel alloy.

In one embodiment the present invention provides a process for manufacturing flexible substrates with a NiCrOₓ tie layer, specifically a method for deposition of NiCrOₓ tie layer on a polymer such as polyimide (PI) film in roll-to-roll form. The method employs reactive sputtering from a NiCr alloy target (80% Ni, 20% Cr by weight) in an atmosphere containing a mixture of argon and oxygen to deposit a NiCrOₓ tie layer. The ratio of oxygen flow/argon flow introduced into sputter can be from 1% to 50%. The tie layer has a copper seed layer adhered to it. The copper seed layer has a thickness of about 100 nm to 1000 nm. The copper layer can be further plated to a thickness of 1 μm to 80 μm.

We also found that the flexible circuit substrates having the NiCrOₓ tie layer demonstrated improved peel strength retention after thermal aging. For example, after thermal heating at 250° C. for 60 minutes, the substrate with a NiCrOₓ tie layer thickness of 40 Angstroms formed by sputtering in an atmosphere having a O₂/Ar flow ratio of 10%, had a higher peel strength retention of 2.99 pounds per inch (lb/in) compared to the substrate with a NiCr tie layer, the latter tie layer formed by sputtering in an atmosphere of pure argon only. A general trend is that peel strength retention after thermal aging increases with the increase of NiCrOₓ thickness and oxygen content of the sputtering gases, with a greater influence being observed by increasing the oxygen content of the sputtering gases.

Different tie layer constructions and deposition processes are widely known and used for the manufacture of flexible circuit substrates, especially for the manufacture of tin plated flexible circuits to be bonded by eutectic bonding technology, regardless of whether an additive or a subtractive circuit manufacturing process is to be subsequently employed.

Circuits may be made by a number of suitable methods such as subtractive, additive-subtractive, and semi-additive.

In a typical subtractive circuit-making process, a dielectric substrate is first provided. The dielectric substrate may be a polymer film made of, for example, polyester, polyimide, liquid crystal polymer, polyvinyl chloride, acrylate, polycarbonate, or polyolefin usually having a thickness of about 10 μm to about 600 μm. After the tie layer of the present invention is deposited, a conductive layer may be deposited by known methods such as vapor deposition or sputtering. Optionally, the deposited conductive layer(s) can be plated up further to a desired thickness by known electroplating or electroless plating processes.

The conductive layer can be patterned by a number of well-known methods including photolithography. If photolithography is used, photoresists, which may be aqueous or solvent based, and may be negative or positive photoresists, are then laminated or coated on at least the metal-coated side of the dielectric substrate using standard laminating techniques with hot rollers or any number of coating techniques (e.g. knife coating, die coating, gravure roll coating, etc.). The thickness of the photoresist is from about 1 μm to about 50 μm. The photoresist is then exposed to ultraviolet light or the like, through a mask or phototool, crosslinking the exposed portions of the resist. The unexposed portions of the photoresist are then developed with an appropriate solvent until desired patterns are obtained. For a negative photoresist, the exposed portions are crosslinked and the unexposed portions of the photoresist are then developed with an appropriate solvent.

The exposed portions of the conductive layer are etched away using an appropriate etchant. Then the exposed portions of the tie layer are etched away a suitable etchant. The remaining (unexposed) conductive metal layer preferably has a final thickness from about 5 nm to about 200 μm. The crosslinked resist is then stripped off the laminate in a suitable solution.

If desired, the dielectric film may be etched to form features in the substrate. Subsequent processing steps, such as application of a covercoat and additional plating may then be carried out.

Another possible method of forming the circuit portion would utilize semi-additive plating and the following typical step sequence:

A dielectric substrate may be coated with a tie layer of the present invention. A thin first conductive layer may then be deposited using a vacuum sputtering or evaporation technique. The materials and thicknesses for the dielectric substrate and conductive layer may be as described in the previous paragraphs.

The conductive layer can be patterned in the same manner as described above in the subtractive circuit-making process. The first exposed portions of the conductive layer(s) may then be further plated using standard electroplating or electroless plating methods until the desired circuit thickness in the range of about 5 nm to about 50 μm is achieved.

The cross-linked exposed portions of the resist are then stripped off. Subsequently, the exposed portions of the thin first conductive layer(s) is/are etched with an etchant that does not harm the dielectric substrate. If the tie layer is to be removed where exposed, it can be removed with appropriate etchants.

If desired the dielectric film may be etched to form features in the substrate. Subsequent processing steps, such as application of a covercoat and additional plating may then be carried out.

Another possible method of forming the circuit portion would utilize a combination of subtractive and additive plating, referred to as a subtractive-additive method, and the following typical step sequence:

A dielectric substrate may be coated with a tie layer of the present invention. A thin first conductive layer may then be deposited using a vacuum sputtering or evaporation technique. The materials and thicknesses for the dielectric substrate and conductive layer may be as described in the previous paragraphs.

The conductive layer can be patterned by a number of well-known methods including photolithography, as described above. When the photoresist forms a positive pattern of the desired pattern for the conductive layer, the exposed conductive material is typically etched away using a suitable etchant. The tie layer is then etched with a suitable etchant. The remaining (unexposed) conductive layer preferably has a final thickness from about 5 nm to about 200 μm. The exposed (crosslinked) portion of the resist is then stripped.

If desired the dielectric film may be etched to form features in the substrate. Subsequent processing steps, such as application of a covercoat and additional plating may then be carried out.

The present invention will now be described in more detail with reference to the following non-limiting experimental section.

### EXPERIMENTAL

The film used in our study will focused on KAPTON E polyimide, however this invention can be applied to other types of polyimide (PI) and even other polymer substrates.

### Comparative Example 1-4

A set of flexible circuit substrates as known in the art were prepared with different levels of NiCr tie layer thicknesses (referring to Table 1) using a production sputter method comprising the steps of.
(1) Polyimide film, KAPTON 1.5E from Dupont was heated at 200-400° C. for 5-30 seconds to remove water from the film in a vacuum chamber.
(2) In Example 1, NiCr alloy tie layer with thickness of 10 Angstroms was deposited by sputtering process. The sputtering condition: chamber pressure of 2-10 mTorr; sputtering power of 1.76 kW and sputtering dwell time of 1.5 seconds. The argon gas flow was fixed at 450 sccm for all the sputtering conditions in the experiment.
   The deposition of different tie layer thicknesses for Example 2, 3 and 4 were realized by varying sputtering power and sputtering dwell time.
(3) A seed copper layer with a thickness of 200 nm was sputtered onto the NiCr tie layer at 3 to 5 mTorr.
(4) A thin flash copper layer with a thickness of 2.3 μm was electroplated onto the sputtered copper layer.

Flexible circuits with a design of 40-50 μm pitches (totally 842 traces) then were produced by additive processing using the different tie layer thickness substrates. A layer of tin with a total/pure tin thickness of 0.51 μm/0.21 μm was plated on the circuits.

A TAB (Tape Automation Bonder) bonder (Shibaura-TTI 810) was employed to bond all the flexible circuits. An aggressive bonding condition (490° C. stage temp, 220° C. tool temp, 220N force and 120 μm forming) was purposely chosen to differentiate the impact of different NiCr tie layer thicknesses on the response of PI/Cu interface delamination.

The PI/Cu delamination levels of the bonded circuits were quantified according to Sn—Au eutectic penetration/coverage percentage across the width of copper traces. The relationship of PI/Cu delamination responses with tie layer conditions is shown in Table 1. It can be seen that around 100% PI/Cu interface delamination occurred on these NiCr substrates.

TABLE 1

| | Tie layer | Sputtering | Tie layer | Percentage of PI/Cu interface |
|---|---|---|---|---|
| Ex. | material | Gas | thickness | delamination across trace |
| C1 | NiCr | Ar | 10 Å | 100% |
| C2 | NiCr | Ar | 15 Å | 98% |
| C3 | NiCr | Ar | 17 Å | 100% |
| C4 | NiCr | Ar | 20 Å | 98% |

### Example 5-9

Examples of one preferred embodiment of the invention comprises the formation of a set of flexible circuit substrates that have five NiCrOₓ deposition conditions with different tie layer thicknesses (referring to Table 2) sputtered under atmospheres having three different O₂/Ar flow ratios (1%, 5.5% and 10%), as listed in Table 2.

All the processes to produce these five NiCrOₓ substrates are the same as those used in Comparative Example 1-4, except for the tie layer sputtering process. In Example 5, NiCrOₓ tie layer with thickness of 13 Angstroms was deposited by sputtering process at 1% of O₂/Ar ratio. The sputtering condition: chamber pressure of 2-10 mTorr; sputtering power of 2.35 kW and sputtering dwell time of 1.5 second.

The deposition of different NiCrOₓ tie layer thicknesses for Example 6, 7, 8 and 9 were realized by varying sputtering power (2.0-10.0 kW), sputtering dwell time (1.0-5.0 seconds) and O₂/Ar ratio (1%, 5.5% and 10%).

TABLE 2

| | Tie layer | O₂/Ar flow ratio | Tie Layer | Percentage of interface |
|---|---|---|---|---|
| Ex | material | during sputtering | Thickness | delamination across trace |
| 5 | NiCrOₓ | 1% | 13 Å | 28% |
| 6 | NiCrOₓ | 10% | 23 Å | 34% |
| 7 | NiCrOₓ | 5.5% | 24 Å | 15% |
| 8 | NiCrOₓ | 1% | 29 Å | 21% |
| 9 | NiCrOₓ | 10% | 40 Å | 8% |

The circuit making process and bonding conditions were the same as those in Example 1-4. The bonding results are shown in Table 2. By using NiCrOₓ tie layer, PI/Cu interface delamination can be significantly reduced to a level lower than 40%. The NiCrOₓ tie layer with a thickness of 40 Angstroms sputtered under 10% O₂/Ar flow ratio provided the lowest PI/Cu interface delamination and was below 10%.

### Comparative Examples 10-13 and Example 14-18

Substrates of Comparative Examples 10-13 and Examples 14-18 with various tie layer thickness for NiCr and NiCrOₓ (as listed in Table 3) were prepared as in Comparative Examples 1-4 and Examples 5-9, respectively. The copper layer was further electroplated to a thickness of 25 micrometers, and then a subtractive process was used to make substrate peel testing specimens for all substrates. All specimens are peeled at 90° according to IPC-TM-650 standard from The Institute for Interconnecting and Packaging Electronic Circuits, 2215 Sanders Road, Northbrook, Ill., (USA). The initial peel strengths and the peel strength after heating at 250° C. for 60 min are also listed in Table 3.

It can be seen that tie layer conditions (i.e. tie layer thickness, NiCr or NiCrOₓ and oxygen content) do not have a significant effect on the initial peel strength. However, they have a significant effect on peel strength retention after thermal aging. NiCrOₓ with a higher content of oxygen (i.e. 10% O₂) has significantly improved peel strength retention. The effect of tie layer thickness on peel strength retention is less than the effect of oxygen content. After thermal aging of 250° C. for 60 minutes, the NiCrOₓ tie layer with thickness of 40 Angstroms sputtered in an atmosphere with an O₂/Ar ratio of 10%, has a relatively higher peel strength retention of 2.99 pounds per inch (lb/in).

Where in the foregoing description reference has been made to elements or integers having known equivalents, then such equivalents are included as if they were individually set forth.

Although the invention has been described by way of example and with reference to particular embodiments, it is to be understood that modifications and/or improvements may be made without departing from the scope or spirit of the invention.

TABLE 3

| | Tie layer | O₂/Ar ratio during | Tie layer | Initial Peel | Peel Strength thermal |
|---|---|---|---|---|---|
| Ex | material | sputtering | Thickness | Strength (lb/in) | aging (lb/in) |
| C10 | NiCr | Ar only | 15Å | 6.90 | 1.47 |
| C11 | NiCr | Ar only | 17Å | 6.45 | 1.41 |
| C12 | NiCr | Ar only | 20Å | 6.55 | 1.39 |
| C13 | NiCr | Ar only | 34Å | 6.69 | 1.74 |
| 14 | NiCrOₓ | 1% | 13Å | 6.75 | 2.21 |
| 15 | NiCrOₓ | 10% | 23Å | 6.30 | 2.79 |
| 16 | NiCrOₓ | 5.5% | 24Å | 6.68 | 2.62 |
| 17 | NiCrOₓ | 1% | 29Å | 6.77 | 1.80 |
| 18 | NiCrOₓ | 10% | 40Å | 6.89 | 2.99 |

1. (canceled)

2. A circuit substrate comprising:
a dielectric film;
a tie layer comprising an oxide or oxides of a metal or metals upon said dielectric film; and
a layer of a metal or metals forming a trace upon said tie layer, and
a layer of eutectically bondable tin or tin alloy on at least a portion of the layer of metal or metals;
wherein the metal oxide tie layer has been formed by sputtering the metal or metals of the oxide or oxides onto a surface of the film in the presence of an inert atmosphere save for at least one reactive gas content to provide the oxygen of the oxide or oxides.

3. A substrate as claimed in claim 2 wherein the metal or metals upon the tie layer is selected from copper aluminum, silver, gold, and alloys thereof.

4. A substrate as claimed in claim 2 wherein the tie layer contains an oxide of nickel, chromium, cobalt, molybdenum, copper and alloys thereof.

5. A substrate as claimed in claim 2 wherein the tie layer contains oxide of nickel.

6. A substrate as claimed in claim 2 wherein the tie layer has a thickness from 13 Angstroms to 300 Angstroms.

7. A substrate as claimed in claim 6 wherein the tie layer thickness is evaluated by dissolving the tie layer in 15% aqua regia and testing by Inductively Coupled Plasma Atomic Emission Spectrum, wherein thickness conversions from element concentrations are based on the density of solid bulk materials.

8. A substrate as claimed in claim 2 wherein the dielectric film is flexible.

9. A substrate as claimed in claim 6 wherein the dielectric film is selected from any one of polyimide, UPILEX, APICAL, KAPTON E, KAPTON EN, KAPTON H, and KAPTON V.

10. A substrate as claimed in claim 6 wherein the dielectric film is selected from any one of poly(ethylene terephthalate), poly(ethylene naphthalate), Polycarbonate, polyetherimide, polyetheretherketone.

11. A substrate as claimed in claim 2 wherein the metal layer is deposited onto the tie layer by any one or more of electrodeposition, sputtering, and electroless deposition.

12. A substrate as claimed in claim 2 wherein the reactive gas is selected from oxygen, nitrous oxide, nitrogen dioxide, dinitrogen pentoxide, and dinitrogen tetraoxide.
